(19) United States
(12) Patent Application Publication
(10) Pub. No.: US 2007/0115012 A1
(43) Pub. Date: May 24, 2007

(54) Reinforced guide panel for vertical probe card

(75) Inventors: Chih-Yung Cheng, Hsinchu Hsiang (TW); H. K. Fan, Hsinchu Hsiang (TW); Chih-Chung Chen, Hsinchu Hsiang (TW); Hsin-Hung Lin, Hsinchu Hsiang (TW)

Correspondence Address: BROWDY AND NEIMARK, P.L.L.C.;624 NINTH STREET, NW, SUITE 300, WASHINGTON, DC, 20001-5303, US

(73) Assignee: MJC Probe Incorporation, Chu-Pei City (TW)

(21) Appl. No.: 11/512,249

(22) Filed: Aug. 30, 2006

(30) Foreign Application Priority Data
Nov. 24, 2005 (TW) 94141359

(51) Int. Cl. G01R 31/02

(52) U.S. Cl. 324/754

(57) ABSTRACT

A guide panel for a vertical probe card is disclosed to have a via area and a reinforcing area. The via area has a plurality of feed through vias. The reinforcing area is bonded to the via area. The reinforcing area has a plurality of through holes in communication with the feed through vias and a plurality of reinforcing ribs formed around the through holes and bonded to the via area.

### BACKGROUND OF THE INVENTION

1. Field of the Invention

The present invention relates to a guide panel for a vertical probe card and more specifically, to a guide panel having a reinforced structure.

2. Description of the Related Art

A vertical probe card uses a plurality of vertical probe pins to contact test points of the electronic component under test for enabling the test of the electric characteristics of the electronic component. In order to prohibit the vertical probe pins of the vertical probe card from sideway displacement and anisotropic curving, guide panels having feed through vias are used to guide movement of the vertical probe pins in the axial direction of the feed through vias during test, so that probing of the test points of electronic component can be smoothly achieved.

However, following fast development of modern technology, the test area on each test procedure is relatively larger, and a single electronic component to be tested has relatively a bigger count of test points. Further, it is not economic to test one single electronic component in one test step (it is the market trend to test multiple electronic components under test in one single test step). Therefore, the guide panels for vertical probe card must be made having a relatively large area. Further, following the development of electronic components having a relatively smaller pitch among test points, it is required to have smaller vertical probe pins to fit the pitch. Therefore, under the limitation of space constraint, it is the market trend to provide guide panels having the characteristic of thin wall thickness.

However, when increasing the area of a guide panel and reducing its wall thickness, the structural strength of the guide panel becomes weak, and the guide panel may be deformed easily. This problem may occur in the conventional guide panel design such as U.S. Pat. No. 6,297,657 B1.

U.S. Pat. No. 5,977,787 discloses a multiple-chip probe assembly suitable for wafer testing over a wide temperature range, which uses a support structure to support buckling beam probe elements. The support structure includes a principal support material having a thermal coefficient of expansion matched with the wafer under test and a second material other than the principal support material, wherein a contact positioning of the plurality of buckling beam probe elements upon the wafer under test during a testing operation is maintained. The second material prevents an individual probe element from electrically contacting the principal support material. However, because the second material is made out of polyimide (PI), it wears quickly with use, doing little help to mechanical structural strength of the support structure. U.S. Pat. No. 6,163,162 discloses a temperature compensated vertical pin probing device, which is constructed with a housing spaced upper and lower dies of Invar®, which substantially matches the coefficient of thermal expansion of the silicon wafer being probed. Spaced slots in the top and bottom dies of the housing contain inserts of Vespel®. The inserts are provided with matching patterns of holes supporting probe pins and insulating the probe pins from the housing. This design has a limitation to the pitch of probe pins. Further, spaced upper and lower dies of Invar® are not used to reinforce the structural strength of the probing device. Therefore, this design cannot prevent deformation, and the pitch precision is not easy to maintain. Further, the installation procedure of this design is complicated.

### SUMMARY OF THE INVENTION

The present invention has been accomplished under the circumstances in view. It is the main object of the present invention to provide a guide panel for a vertical probe car, which has the mechanical structural strength well reinforced against deformation.

To achieve this object of the present invention, the guide panel comprises a via area and a reinforcing area bonded to the via area. The via area has a plurality of feed through vias for insertion of the probe pins of the vertical probe card. The reinforcing area has at least one through hole in communication with the feed through vias and at least one reinforcing rib formed around the at least one through hole and bonded to the via area.

In a preferred embodiment of the present invention, the guide panel includes a substrate defining the via area and a reinforcing board defining the reinforcing area and having a plurality of through holes. The reinforcing board is bonded with its top side to the bottom side of the substrate so that the through holes are respectively axially aligned with the feed through vias one by one.

In another preferred embodiment of the present invention, the guide panel is formed by a single substrate having a top portion defining the via area and a bottom portion defining the reinforcing area.

In still another preferred embodiment of the present invention, the reinforcing area has a plurality of through holes, each of which is in communication with a plurality of the feed through vias.

In still another preferred embodiment of the present invention, the reinforcing area has only one through hole in communication with all of the feed through vias of the via area.

### BRIEF DESCRIPTION OF THE DRAWINGS

FIGS. 1A-1D are schematic drawings illustrating steps of making a guide panel according to a first preferred embodiment of the present invention.

FIGS. 2A-2D are schematic drawings illustrating steps of making a guide panel according to a second preferred embodiment of the present invention.

FIGS. 3A-3C are schematic drawings illustrating steps of making a guide panel according to a third preferred embodiment of the present invention.

FIG. 4 is a schematic sectional view showing the structure of a guide panel according to a fourth preferred embodiment of the present invention.

FIG. 5 is a schematic bottom view in an enlarged scale of the guide panel shown in FIG. 4.

FIG. 6 is a schematic sectional view showing the structure of a guide panel according to a fifth preferred embodiment of the present invention.

FIG. 7 is a schematic bottom view in an enlarged scale of the guide panel shown in FIG. 6.

### DETAILED DESCRIPTION OF THE INVENTION

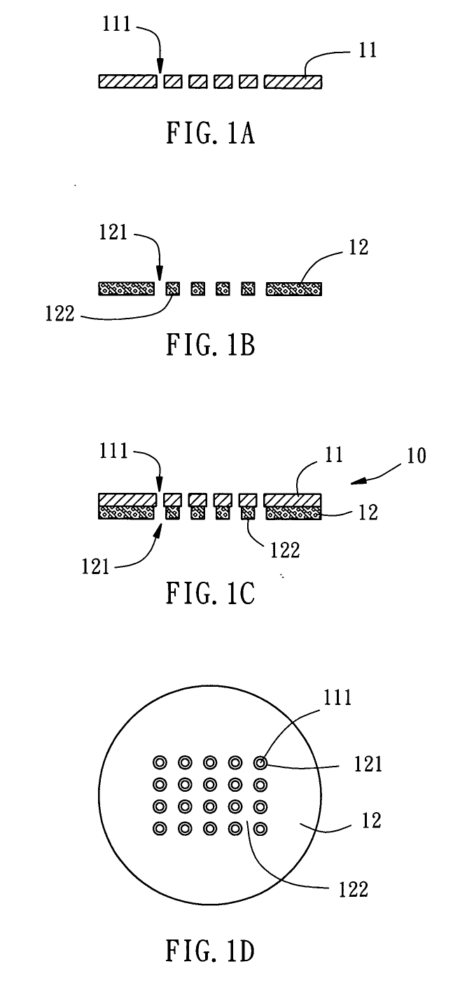

FIGS. 1A-1D are schematic drawings illustrating the steps of a method for making a guide panel 10 according to a first preferred embodiment of the present invention. According to this embodiment, the method includes the following steps.

(A) As shown in FIG. 1A, prepare a thin substrate 11 made of a silicon material and then form feed through vias 111 on the substrate 11 by an anisotropic etching. In this embodiment, the substrate 11 has a thickness smaller than 1 mm. In practice, the thickness of the substrate 11 can be thinner subject to the pin diameter of the probe pins of the vertical probe card. As shown in FIG. 1A, the substrate 11 defines a via area including the feed through vias 111, and the feed through vias 111 are formed through the top and bottom sides of the via area.

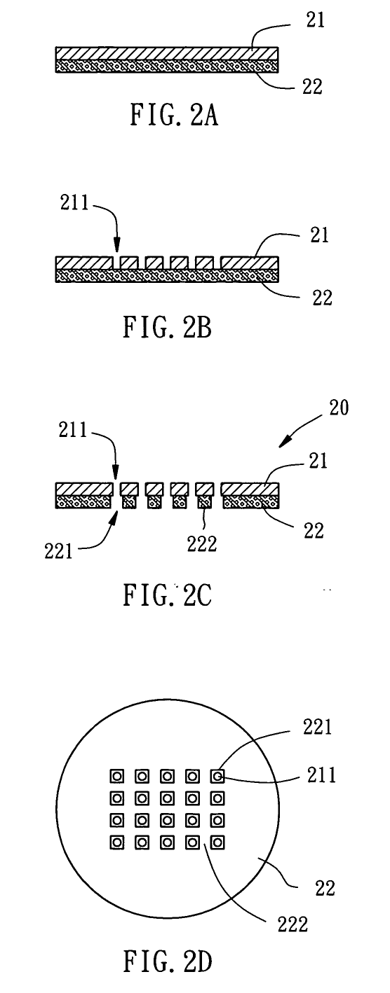

(B) As shown in FIG. 2B, prepare a reinforcing board 12 made of silicon material and then form through holes 121 of greater diameter than the feed through vias 111 on the reinforcing board 12 by an anisotropic etching. In this embodiment, the reinforcing board 12 has a thickness smaller than 1 mm. In practice, the thickness of the reinforcing board 12 can be thinner subject to the pin diameter of the probe pins of the vertical probe card. The reinforcing board 12 defines a reinforcing area including the through holes 121 and a plurality of reinforcing ribs 122, i.e. the unetched portion of the reinforcing board 12, around the through holes 121.

(C) As shown in FIGS. 1C and 1D, the top side of the reinforcing board 12 is bonded to the bottom side of the substrate 11 by any of a variety of fastening or bonding technique or means, keeping the through holes 121 of the reinforcing board 12 in axial alignment with the feed through vias 111 of the substrate 11 in a coaxial manner such that the reinforcing ribs 112 support the via area of the substrate 11 between each two adjacent feed through vias 111.

As indicated above, the guide panel 10 provided by the present invention has a via area with feed through vias 111 and a reinforcing area bonded to the via area. Because the through holes 121 of the reinforcing area are respectively aligned with the feed through vias 111 of the via area, the reinforcing area does not interfere with the insertion of the respective probe pins. Further, because the through holes 121 in the reinforcing area have a diameter greater than the feed through vias 111, the sideway biasing of the inserted probe pins can be effectively limited by the feed through vias 111 as the conventional guide panel did. Further, the reinforcing ribs 121 greatly enhance the structural strength of the whole assembly, preventing deformation of the guide panel 10. Because of the structural reinforcing effect of the reinforcing area, the guide panel 10 can be made having a large area to fit modern probing requirements. Further, the via area and the reinforcing area can be made of same or different materials/methods subject to different requirements. Therefore, the manufacturer can select the most cost-saving material/method to make the guide panel for saving the manufacturing cost.

Further, except the anisotropic etching, conventional mechanical drilling or laser processing techniques may be employed to make feed through vias on the substrate.

Furthermore, the bonding between the via area (substrate) and reinforcing area (reinforcing board) can be done with or without a bonding medium. The bonding technique without a bonding medium can be anodic bonding or fusion bonding. The bonding technique with a bonding medium can be adhesive bonding, eutectic bonding, or glass frit bonding.

FIGS. 2A-2D illustrate the steps of a method for making a guide panel 20 according to a second preferred embodiment of the present invention. According to this embodiment, the method includes the following steps.

(A) As shown in FIG. 2A, bond a thin substrate 21 and a reinforcing board 22 together. The substrate 21 and the reinforcing board 22 are made of silicon material and have a thickness smaller than 1 mm respectively. In practice, the thickness of the substrate 21 and the thickness of the thick reinforcing board 22 can be determined subject to the pin diameter of the probe pins of the vertical probe card. The bottom side of the substrate 21 is bonded to the top side of the reinforcing board by any of a variety of fastening or bonding technique or means for enabling the substrate 21 to define a via area and the reinforcing board 22 to define a reinforcing area.

(B) As shown in FIG. 2B, a plurality of feed through vias 211 are formed by an anisotropic etching on the substrate 21 within the via area through the top and bottom sides of the feed through hole area.

(C) As shown in FIGS. 2C and 2D, through holes 221 of greater diameter than the feed through vias 211 are formed on the reinforcing board 22 by an anisotropic etching within the reinforcing area through the top and bottom sides of the reinforcing area in axial alignment with the feed through vias 211 on the substrate 21 in a coaxial manner so that a plurality of reinforcing ribs 112, i.e. the unetched portion of the reinforcing board 22, are defined in the reinforcing area around the through holes 221 to support the via area of the substrate 21 between each two adjacent feed through vias 211.

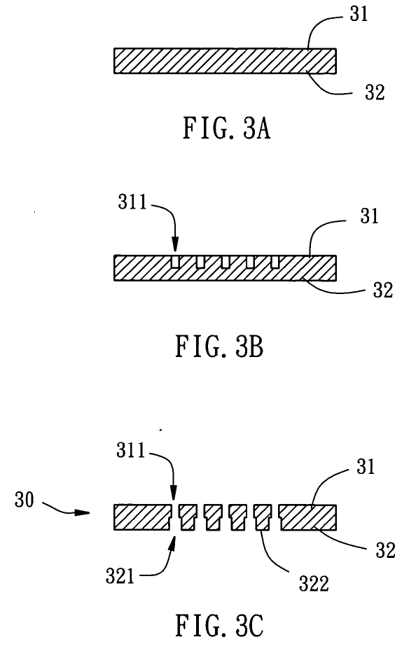

FIGS. 3A-3C illustrate the steps of a method for making a guide panel 30 according to a third preferred embodiment of the present invention. According to this embodiment, the method includes the following steps.

(A) As shown in FIG. 3A, a thin substrate made of silicon material is provided. The substrate has an upper portion defining an upper via area 31 having a thickness smaller than 1 mm and a bottom portion defining a lower reinforcing area 32 having a thickness smaller than 1 mm.

(B) As shown in FIG. 3B, a plurality of feed through vias 311 are formed by an anisotropic etching on the upper via area 31 subject to a predetermined diameter and depth.

(C) As shown in FIG. 3C, a plurality of through holes 321 of greater diameter than the feed through vias 311 are formed by an anisotropic etching on the lower reinforcing area 32 in communication with the feed through vias 311 respectively so as to form a plurality of reinforcing ribs 322, i.e. the unetched portion of the reinforcing area, in the lower reinforcing area 32 around the through holes 321 to support the upper via area 31 between each two adjacent feed through vias 311.

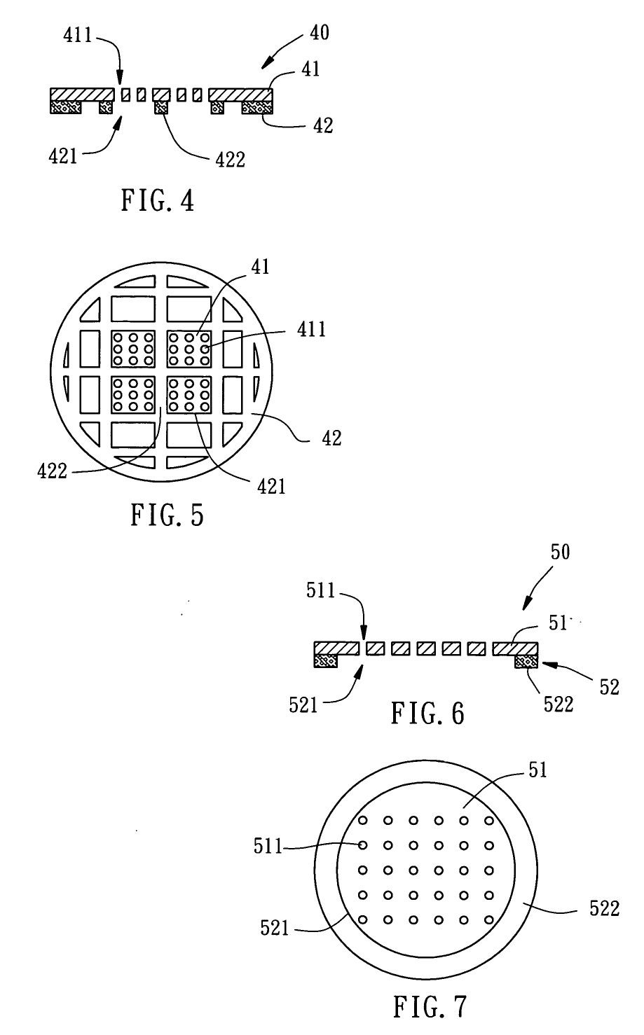

FIGS. 4 and 5 illustrate a guide panel 40 according to a fourth preferred embodiment of the present invention. According to this embodiment, the guide panel 40 comprises a thin substrate defining an upper via area 41 and a lower reinforcing area 42. The upper via area 41 has a plurality of feed through vias 411 formed through the top and bottom sides thereof by an anisotropic etching. The lower reinforcing area 42 has a plurality of rectangular through holes 421 formed through the top and bottom sides thereof by an anisotropic etching at locations respectively corresponding to some of the feed through vias 411 on the upper via area 41, and a plurality of reinforcing ribs 422 formed around the rectangular through holes 421 and supported at the bottom side of the upper via area 41 to reinforce the structural strength of the guide panel 40. This design of guide panel 40 makes the guide panel can be made with a large area size, and the fabricated guide panel 40 is durable in use against deformation. Further, a polymer coating, for example, polyimide (not shown) may be coated on the guide panel 40 to enhance the toughness of the structure or the lubricity of the feed through vias 411. Furthermore, the guide panel 40 may be further processed to provide a fastening structure (not shown) for fastening to the probe head of a probe card or other device.

FIGS. 6 and 7 illustrate a guide panel 50 having a via area 51 and a reinforcing area 52 according to a fifth preferred embodiment of the present invention. The via area 51 has a plurality of feed through vias 511 through the top and bottom sides thereof. The reinforcing area 52 has a circular through holes 521 through the top and bottom sides thereof in communication with the feed through vias 511, i.e. the area of the circular through hole 521 covers the area of the feed through vias 511, and a reinforcing rib 522 formed around the circular through hole 521 and supported at the bottom side of the via area 51 around the feed through vias 511 to reinforce the structural strength of the guide panel 50.

Further, an insulative material such as SiO₂, Al₂O₃, TiO₂, or any of a variety of suitable dielectric materials may be coated on the guide panel 50 to enhance the electric insulative characteristic of the guide panel 50.

In conclusion, the reinforcing rib of the present invention is adapted to reinforce the structural strength of the guide panel. Therefore, the reinforcing rib can be made in a latticed, circular, polygonal, or any of a variety of shape that can support the via area.

What is claimed is:

1. A guide panel for a vertical probe card, comprising:
a via area having a plurality of feed through vias; and
a reinforcing area connected to said via area, said reinforcing area having at least one through hole disposed in communication with at least one of said feed through vias, and at least one reinforcing rib disposed around said at least one through hole of said reinforcing area and abutted to said via area.

2. The guide panel as claimed in claim 1, wherein said via area has a thickness smaller than 1 mm.

3. The guide panel as claimed in claim 1, wherein said reinforcing area has a thickness smaller than 1 mm.

4. The guide panel as claimed in claim 1, further comprising a substrate defining said via area and a reinforcing board defining said reinforcing area; wherein the reinforcing board is bonded to the substrate by a fastening means.

5. The guide panel as claimed in claim 1, further comprising a substrate defining said via area and a reinforcing board defining said reinforcing area; wherein the reinforcing board is bonded to the substrate.

6. The guide panel as claimed in claim 5, wherein said reinforcing board is bonded to said substrate by a bonding technique selected from the group consisting of anodic bonding, fusion bonding, adhesive bonding, eutectic bonding and glass frit bonding.

7. The guide panel as claimed in claim 1, wherein said feed through vias of said via area are formed by means of anisotropic etching.

8. The guide panel as claimed in claim 1, wherein said at least one through hole of said reinforcing area is formed by means of anisotropic etching.

9. The guide panel as claimed in claim 1, further comprising a fastening structure for connection to an external device.

10. The guide panel as claimed in claim 1, wherein the guide panel is made of silicon material.

11. The guide panel as claimed in claim 1, further comprising a substrate, which has an upper portion defining said via area and a bottom portion defining said reinforcing area.

12. The guide panel as claimed in claim 1, wherein the guide panel is coated with polymer.

13. The guide panel as claimed in claim 12, wherein said polymer is polyimide.

14. The guide panel as claimed in claim 1, wherein the guide panel is coated with a layer of insulative material.

15. The guide panel as claimed in claim 14, wherein said insulative material is selected from one of the group consisting of SiO₂, Al₂O₃, and TiO₂.

16. The guide panel as claimed in claim 1, wherein said reinforcing area has a plurality of said through holes respectively aligned with said feed through vias one by one, and a plurality of said reinforcing ribs formed around said through holes.

17. The guide panel as claimed in claim 1, wherein said reinforcing area has a plurality of said through holes, each of which corresponds to a plurality of said feed through vias, and a plurality of said reinforcing ribs formed around said through holes.

18. The guide panel as claimed in claim 1, wherein said reinforcing area has one said through hole in communication with all of said feed through vias, and one said reinforcing rib surrounding said through hole.

19. The guide panel as claimed in claim 1, wherein said at least one reinforcing rib has a latticed shape.

20. The guide panel as claimed in claim 1, wherein said at least one reinforcing rib has an annular shape.

21. The guide panel as claimed in claim 1, wherein said at least one reinforcing rib has a polygonal shape.

22. The guide panel as claimed in claim 1, wherein said at least one reinforcing rib has an irregular shape.

23. The guide panel as claimed in claim 1, wherein said at least one through hole of said reinforcing area has a diameter grater than that of said feed through vias.
